(19) United States
(12) Patent Application Publication
(10) Pub. No.: US 2025/0088392 A1
(43) Pub. Date: Mar. 13, 2025

(54) RECEIVER CIRCUIT AND SEMICONDUCTOR DEVICE

(71) Applicant: TAIWAN SEMICONDUCTOR MANUFACTURING COMPANY LTD., HSINCHU (TW)

(72) Inventors: SHU-CHUN YANG, CHANGHUA COUNTY (TW); WEI CHIH CHEN, HSINCHU CITY (TW)

(21) Appl. No.: 18/465,949

(22) Filed: Sep. 12, 2023

(51) Int. Cl. H04L 25/02; H03K 5/134; H03K 5/24

(52) U.S. Cl. CPC H04L 25/0292; H03K 5/134; H03K 5/2481; H04L 25/0272

(57) ABSTRACT

The present disclosure provides a receiver circuit, which includes: a first comparator circuit, a second comparator circuit, and an inverter circuit. The inverter circuit has a first input terminal and a second input terminal. A first output terminal of the first comparator circuit is electrically connected to the first input terminal of the inverter circuit, and a second output terminal of the second comparator circuit is electrically connected to the second input terminal of the inverter circuit.

### BACKGROUND

The present disclosure relates to digital circuits, and, in particular, to a receiver circuit and a semiconductor device.

With advent of technologies, a system-on-chip (SoC) may include a plurality of integrated circuits (IC), and it is possible to package these ICs in the same semiconductor package. In an SoC, a die can be partitioned into several chiplets. Such partitioning improves design flexibility and reduces non-recurring design cost. With the explosive growth of the input/output (I/O) data rate, the timing window for a receiver IC or chiplet can become narrow. If a skew occurs in one or more data lines of the data transmission channel between two ICs or chiplets, it can cause low data quality to the receiver IC or chiplet.

Thus, there is demand for a receiver circuit and a semiconductor device to solve the aforementioned problem.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is a diagram illustrating a semiconductor package in accordance with an embodiment of the present disclosure.

FIG. 2A is a diagram of the receiver amplifier 111 in accordance with the embodiment of FIG. 1.

FIG. 2B is a diagram illustrating the relationship between the input voltage Vin and output voltage Vout of the receiver amplifier 111 of FIG. 2A.

FIG. 2C is a diagram illustrating the relationship between the input voltage Vin and the gain of the receiver amplifier 111 in FIG. 2A.

FIGS. 2D-2F are diagrams illustrating different cross points of the receiver amplifier 111 in FIG. 2A.

FIG. 3A is a schematic diagram of the receiver amplifier 111 in accordance with the embodiment of FIG. 1.

FIG. 3B is a schematic diagram of the inverter in accordance with the embodiment of FIG. 3A.

FIG. 3C is another schematic diagram of the inverter in accordance with the embodiment of FIG. 3A.

FIG. 4 is a schematic diagram of the receiver amplifier 111 in accordance with another embodiment of the present disclosure.

FIG. 5A is a schematic diagram of a comparator circuit 500 in accordance with an embodiment of the present disclosure.

FIG. 5B is a diagram illustrating the relationship between the input voltage Vin and the output voltage VOUT of the comparator circuit 500 in FIG. 5A.

FIG. 6A is a schematic diagram of a comparator circuit 600 in accordance with an embodiment of the present disclosure.

FIG. 6B is a diagram illustrating the voltages Vout1 and Vout2 of the comparator circuit 600 over time in FIG. 6A.

FIG. 6C is a diagram illustrating the relationship between the input voltage Vin and the output voltage VOUT of the comparator circuit 600 in FIG. 6A.

FIG. 7A is a schematic diagram of a differential amplifier 710 in accordance with the embodiments of FIG. 5A and FIG. 6A.

FIG. 7B is a Bode plot illustrating the frequency response of the differential amplifier 710 in FIG. 7A.

FIG. 8A is a Bode plot illustrating the frequency response of the differential amplifier 610 in FIG. 6.

FIG. 8B is a diagram illustrating the frequency response of the differential amplifier 610 in FIG. 6.

FIG. 9A is an eye diagram of the comparator circuit 600 in accordance with the embodiment of FIG. 6A.

FIG. 9B is a diagram illustrating the relationship between the reference voltage VREF and the eye opening in accordance with the embodiment of FIG. 6A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

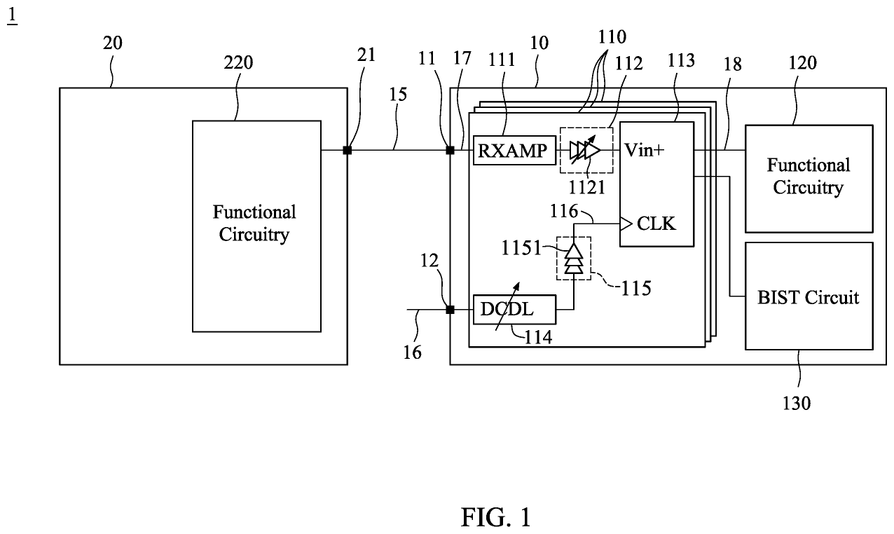

FIG. 1 is a diagram illustrating a semiconductor package 1 in accordance with an embodiment of the present disclosure.

In an embodiment, the semiconductor package 1 may include semiconductor devices 10 and 20. The semiconductor device 10 may be electrically connected to the semiconductor device 20 through a data bus 15, which may include a data signal DQ[N−1:0], where N denotes the number of data bits. In some embodiments, the semiconductor devices 10 and 20 may be semiconductor dies, semiconductor chips, or chiplets, but the present disclosure is not limited thereto. The semiconductor devices 10 and 20 may be encapsulated in an encapsulant (not shown) of the semiconductor package 1.

As depicted in FIG. 1, the semiconductor device 20 may include functional circuitry 220 having a transmitter to transmit the data signal DQ[N−1:0] to the semiconductor device 10 over the data bus 15 via the connection element 21, wherein the number N may denote the data width of the data bus 15. The semiconductor device 10 may include a plurality of receiver circuits 110, functional circuitry 120, and a built-in self-test (BIST) circuit 130. Each of the receiver circuits 110 may be configured to receive a respective data bit of a data signal DQ[N−1:0] transmitted from the functional circuitry 220 of the semiconductor device 20 via a respective connection element 11, and to receive a data strobe signal 16 (e.g., DQS signal) via a respective connection element 12. In some embodiments, the connection elements 11, 12, and 21 may be bump pads, micro bumps, solder balls, etc., but the present disclosure is not limited thereto.

Each of the receiver circuits 110 may include a plurality of receiver amplifiers (RXAMP) 111, a plurality of delay circuits 112, a plurality of D flip-flops 113, a plurality of digitally controlled delay lines 114, and a plurality of delay circuits 115. More specifically, each receiver circuit 110 may be configured to receive a corresponding data bit of the data signal DQ[N−1:0] from the respective connection element 11, and to perform skew calibration on the received data bit. In addition, the data bit received by each receiver circuit 110 may have a corresponding receiver amplifier 111, delay circuit 112, D flip-flop 113, digitally controlled delay line 114, and delay circuit 115.

For example, the receiver amplifier 111 may be configured to amplify the voltage swing of the received data bit, such as amplifying the amplitude of the received data bit to the power supply voltage (e.g., VCCIO) of the receiver circuit 110. The data bit received by the receiver circuit 110 via the respective connection element 11 may have a low voltage swing range, which may be not sufficient to allow the corresponding delay circuit 112 (e.g., which may include a plurality of buffer circuits 1121 connected in series) normally. The data bit amplified by the receiver amplifier 111 can reach a full voltage swing range which can allow the corresponding delay circuit 112 to functional normally. After the amplified data bit is delayed by the delay circuit 112, the delayed data bit can be sampled at an input terminal Vin+ of the corresponding D flip-flop 113 when the delayed data strobe signal 116 generated by the digitally controlled delay line 114 and the delay circuit 115 (e.g., which may include a plurality of buffer circuits 1151 connected in series) is at a rising edge (or a falling edge). Here, the delayed data strobe signal 116 may be regarded as a clock signal of the corresponding D flip-flop 113.

In some embodiments, the data bit 18 output by the D flip-flop 113 of each receiver circuit 110 can be collectively transmitted to the functional circuit 120 for subsequent processing. In some embodiments, when a test mode of the semiconductor device 10 is activated (e.g., by a scan enable signal), the data bit 18 output by the D flip-flop 113 of each receiver circuit 110 can be collectively transmitted to the BIST circuit 130 for subsequent testing. When the test mode of the semiconductor device 10 is activated, the BIST circuit 130 may be configured to the functionality of the functional circuitry 120 based on a scan data signal from the semiconductor device 20 or external test equipment. In addition, the BIST circuit 130 may be further configured to build an eye diagram of the data signal received from the connection element 11. More specifically, the BIST circuit 130 may be configured to adjust (i.e., sweep) a reference voltage VREF and the delay cycle of the digitally controlled delay line 114 within a predetermined range, thereby building the eye diagram.

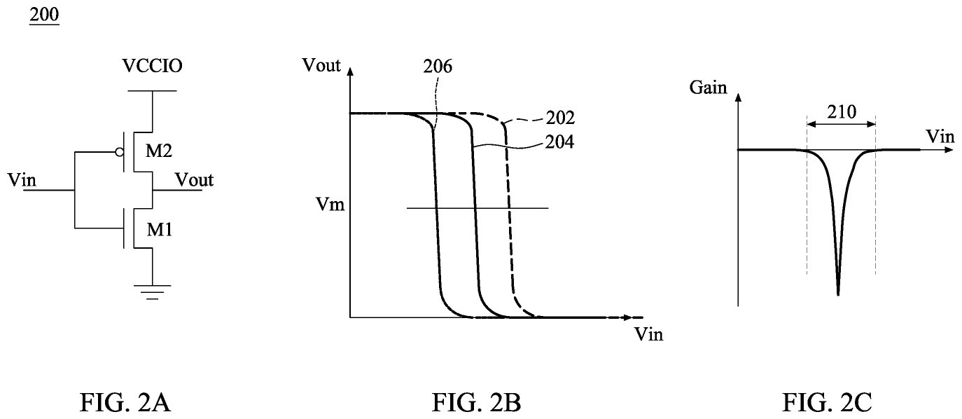

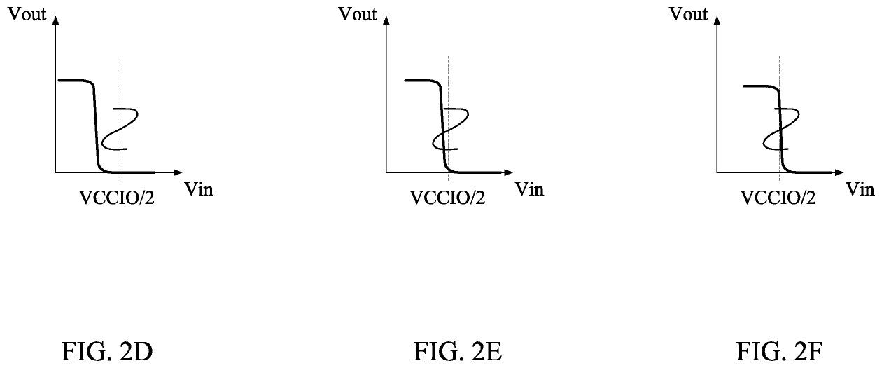

FIG. 2A is a diagram of a receiver amplifier in accordance with the embodiment of FIG. 1. FIG. 2B is a diagram illustrating the relationship between the input voltage Vin and output voltage Vout of the receiver amplifier 111 of FIG. 2A. FIG. 2C is a diagram illustrating the relationship between the input voltage Vin and the gain of the receiver amplifier 111 in FIG. 2A. FIGS. 2D-2F are diagrams illustrating different cross points of the receiver amplifier 111 in FIG. 2A. Please refer to FIG. 2A˜2F.

In some embodiments, the receiver amplifier 111 shown in FIG. 1 may be implemented by a CMOS (complementary metal oxide semiconductor) inverter 200 which may include transistors M1 and M2, as shown in FIG. 2A. For example, the transistor M1 may have a gate electrically connected to the input voltage Vin, a drain connected to an output terminal, and a source being grounded. The transistor M2 may have a gate electrically connected to the input voltage Vin, a drain connected to the output terminal, and a source electrically connected to a power supply voltage VCCIO.

In some embodiments, the voltage cross point between the input voltage Vin and the output voltage Vout of the CMOS inverter 200 shown in FIG. 2A may vary due to variations of the semiconductor manufacturing process, load capacitance, etc. For example, curve 204 shown in FIG. 2B may represent an ideal transfer function of the CMOS inverter 200, and linearity of the CMOS inverter can be considered when the input voltage Vin may be approximately equal to the voltage VCCIO/2. At this time, the voltage Vm may also be approximately equal to the voltage VCCIO/2. That is, the CMOS inverter 200 may function as an amplifier given that the input voltage Vin is approximately swung around the voltage VCCIO/2, as shown in FIG. 2F. In addition, the gain of the CMOS inverter 200 can vary within the range 210 while the gain of the CMOS inverter 200 is kept at a constant outside the range 210, as shown in FIG. 2C.

Curves 202 and 206 shown in FIG. 2B may represent corner conditions of the transfer function of the CMOS inverter 200. For example, given that the voltage cross point between the input voltage Vin and the output voltage Vout is much lower than the voltage VCCIO/2 (i.e., cross point<<VCCIO/2), the voltage swing range of the input voltage Vin may be not within the linearity region of the CMOS inverter 200, and the output voltage Vout will be zero, as shown in FIG. 2D. Given that the voltage cross point between the input voltage Vin and the output voltage Vout is lower than the voltage VCCIO/2 (i.e., voltage cross point<VCCIO/2), a portion of the voltage swing range of the input voltage Vin may be within the linearity region of the CMOS inverter 200. The input voltage Vin is amplified by the CMOS inverter 200 when the input voltage Vin is within the linearity region of the CMOS inverter 200, but the input voltage Vin will not be amplified by the CMOS inverter 200 when the input voltage Vin is not within the linearity region of the CMOS inverter 200, resulting in duty distortion of the output voltage Vout.

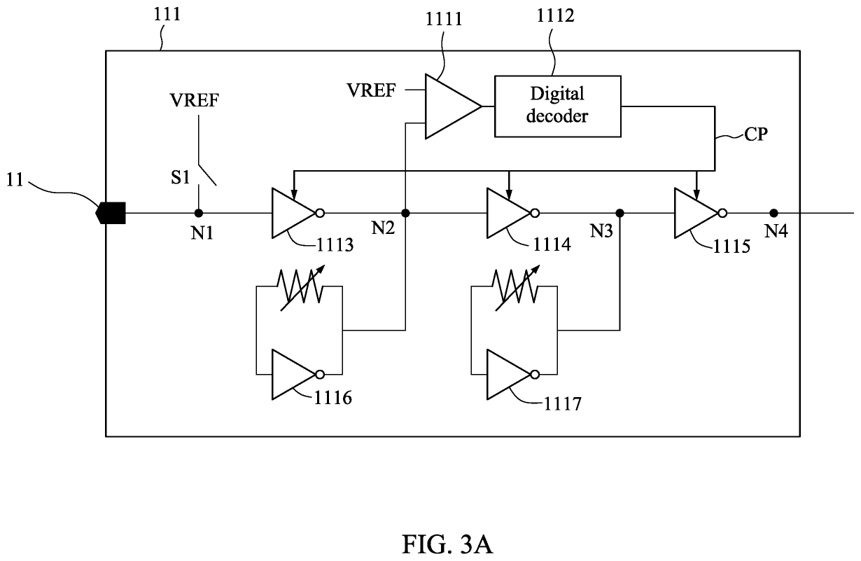

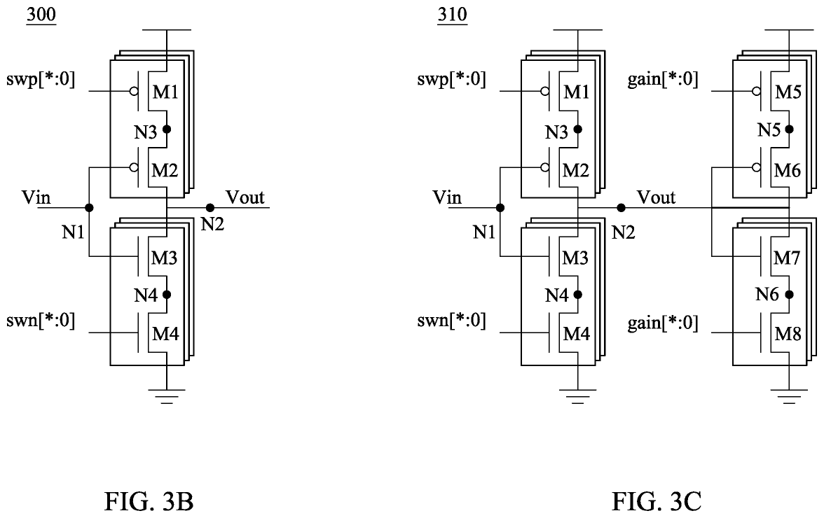

FIG. 3A is a schematic diagram of the receiver amplifier 111 in accordance with the embodiment of FIG. 1. FIG. 3B is a schematic diagram of the inverter in accordance with the embodiment of FIG. 3A. FIG. 3C is another schematic diagram of the inverter in accordance with the embodiment of FIG. 3A. Please refer to FIGS. 3A-3C.

In some embodiments, the receiver amplifier 111 may include a comparator 1111, a digital decoder 1112, inverters 1113˜1117, variable resistors VR1 and VR2, and a switch S1. Each of the inverters 1113˜1115 may be implemented by an adjustable CMOS inverter circuit 300 shown in FIG. 3B, which is controlled by the control parameters CP (e.g., including swp[*.0] and swn[*.0]) generated by the digital decoder 1112. As depicted in FIG. 3B, the adjustable CMOS inverter circuit 300 may include a plurality of stacked CMOS inverters that share the common input terminal (i.e., node N1) and the common output terminal (i.e., node N2). In addition, each of the stacked CMOS inverters may have a respective first-type control bit (e.g., swp[x]) and a respective second-type control bit (e.g., swn[x]), wherein x is an integer between 0 and N−1, and N may present the number of stacked CMOS inverters of the adjustable CMOS inverter circuit 300. In addition, the inverters 1116 and 1117 may be implemented using common CMOS inverters.

For example, each of the stacked CMOS inverters may include transistors M1 to M4, wherein the transistors M1 and M2 may be P-type transistors, and the transistors M3 and M4 may be N-type transistors. Taking the topmost stacked CMOS inverter as an example, the transistor M1 may have a gate electrically connected to the respective first-type control bit (e.g., the least significant bit swp[0] of the control parameter swp[*.0]), a source connected to the power supply voltage AVDD, and a drain connected to node N3. The transistor M2 may have a gate electrically connected to node N1 which receives the input voltage Vin, a source connected to node N3, and a drain connected to node N2 (i.e., the output terminal). The transistor M3 may have a gate electrically connected to node N1, a source connected to node N4, and a drain connected to node N2. The transistors M4 may have a gate electrically connected to the respective second-type control bit (e.g., the least significant bit swn[0] of the control parameter swn[*.0]), a source being grounded, and a drain connected to node N4.

When the calibration mode of the adjustable CMOS inverter circuit 300 is activated, the switch S1 is closed, so the reference voltage VREF can be provided to the input terminal (i.e., node N1) of the adjustable CMOS inverter circuit 300. In addition, since the stacked CMOS inverters in the adjustable CMOS inverter circuit 300 have the common output terminal (i.e., node N2), the voltage at node N2 can be provided to the feedback loop of the inverter 1116 and variable resistor VR1. The voltage at node N2 is further compared with the reference voltage VREF by the comparator 1111. The digital decoder 1112 may generate the control parameters CP (i.e., including swp[*.0] and swn[*.0]), and each of the stacked CMOS inverter can receive the corresponding first-type control bit and the second-type control bit. For example, regarding the topmost stacked CMOS inverter, if the first-type control bit (e.g., swp[0]) and the second-type control bit (e.g., swn[0]) are both in the high logic state, the transistor M1 is turned off.

Afterwards, the voltage at node N2 is compared with the reference voltage VREF again by the comparator 1111 to determine whether the voltage cross point of the inverter 1113 fits the design requirement of the eye diagram. If the voltage cross point of the inverter 1113 fits the design requirement of the eye diagram, it may indicate that the reference voltage VREF at the current time can be used for the inverter 1113, and the calibration procedure of the inverter 1113 is completed. If the voltage cross point of the inverter 1113 does not fit the design requirement of the eye diagram, a lower or higher reference voltage VREF may be used, and the aforementioned calibration procedure may be performed again to determine whether the currently used reference voltage VREF can be used. It should be noted that the aforementioned calibration procedure can be performed repeatedly until the reference voltage VREF appropriate for the inverter 1113 is determined. Once the reference voltage VREF for the inverter 1113 is determined, the switch S1 is opened, and the inverter 1113 can receive the input voltage Vin from the connection element 11. In addition, the reference voltage VREF may be used for the voltage cross point calibration, and it may not be used for eye height SHMOO test since there is no comparison logic in the adjustable CMOS inverter circuit 300.

In some embodiments, the control parameter (i.e., including swp[*.0] and swn[*.0]) of the inverter 1113 can also be applied to the inverters 1114 and 1115. It may indicate that one set of the comparator 1111, digital decoder 1112, and switch S1 can be equipped in the receiver amplifier 111 to calibrate the voltage cross points of the inverters 1113˜1115.

In some embodiments, each of the inverters 1113˜1115 may be calibrated independently, and it may have a respective set of a comparator 1111, digital decoder 1112, and switch S1 for calibrating the voltage cross point thereof. For example, another set of the comparator 1111, digital decoder 1112, and switch S1 (not shown in FIG. 3A) can be designed dedicatedly for the inverter 1114, and the voltage at node N3 can be provided to the feedback loop of inverter 1117 and the variable resistor VR2. The voltage at node N3 can be compared with the reference voltage VREF by the comparator corresponding to the inverter 1114 to generate a comparison result, and the digital decoder corresponding to the inverter 1114 can generate the control parameters CP that are provided to the stacked CMOS inverters to adjust the voltage cross point of the inverter 1114. The calibration procedure can be performed repeatedly until the reference voltage VREF appropriate for the inverter 1114 is determined. In addition, the voltage cross point of the inverter 1115 can be calibrated in a similar manner.

In some embodiments, each of the inverters 1113˜1115 may be implemented by an adjustable CMOS inverter circuit 310 shown in FIG. 3C, which is controlled by the control parameters CP (e.g., including swp[*.0] and swn[*.0]) generated by the digital decoder 1112. The adjustable CMOS inverter circuit 310 shown in FIG. 3C may be similar to the adjustable CMOS inverter circuit 300 shown in FIG. 3B, with the difference therebetween that a plurality of active loads are connected to the output terminal of the stacked CMOS inverters of the adjustable CMOS inverter circuit 310. Each of the active loads may include transistors M5˜M8, and transistors M6 and M7 may use diode-connected configuration. For example, the transistor M5 may have a gate electrically connected to a respective bit of the control parameter gain[*:0], a source connected to the power supply voltage AVDD, and a drain connected to node N5. The transistor M6 may have a gate electrically connected to the output terminal (i.e., node N2) of the stacked CMOS inverter, a source connected to node N5, and a drain connected to node N2. The transistor M7 may have a gate electrically connected node N2, a source connected to node N6, and a drain connected to node N2. The transistor M8 may have a gate electrically connected to the respective bit of the control parameter gain[*:0], a source being grounded, and a drain connected to node N6. Therefore, the transistors M6 and M7 may function as active loads of the CMOS inverter circuit including the transistors M1˜M4.

In addition, the respective bit of the control parameter gain[*:0] may control whether to turn on or turn off the transistors M5 and M8. For example, taking the topmost set of transistors M5˜M8 as an example, if the least significantly bit gain[0] of the control parameter gain[*:0] is in the high logic state, the transistor M5 is turned off, and the transistor M8 is turned on. At this time, the transistor M7 may function as an active load, and the transistor M6 may not be turned on since there is no current flowing through the transistor M5.

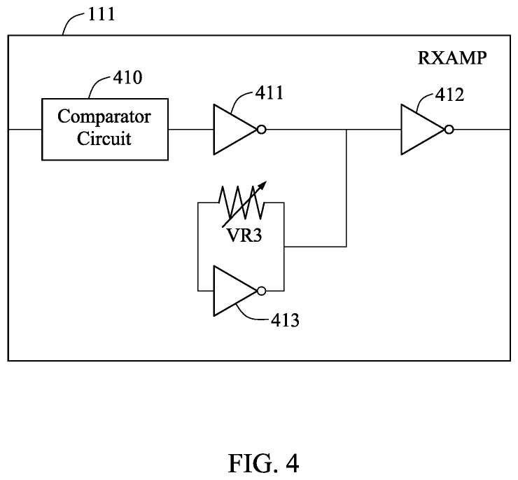

FIG. 4 is a schematic diagram of the receiver amplifier 111 in accordance with another embodiment of the present disclosure. Please refer to FIG. 1 and FIG. 4.

In some embodiments, the receiver amplifier 111 may include a comparator circuit 410, inverters 412 and 413, and a variable resistor VR3. The comparator circuit 410 may include differential amplifiers (not shown in FIG. 4) that can compare the input voltage Vin with the reference voltage VREF, thereby facilitating the BIST circuit 130 to build the eye diagram by sweeping the reference voltage VREF and the data strobe signal delayed by the digitally controlled delay line 114. The output voltage of the comparator circuit 410 may be provided to the feedback loop including the inverter 413 and the variable resistor VR3, and it may pass through the inverters 411 and 412 to generate the amplified data signal. More details of the differential amplifiers and the configuration of their subsequent CMOS inverter will be described in the following embodiments.

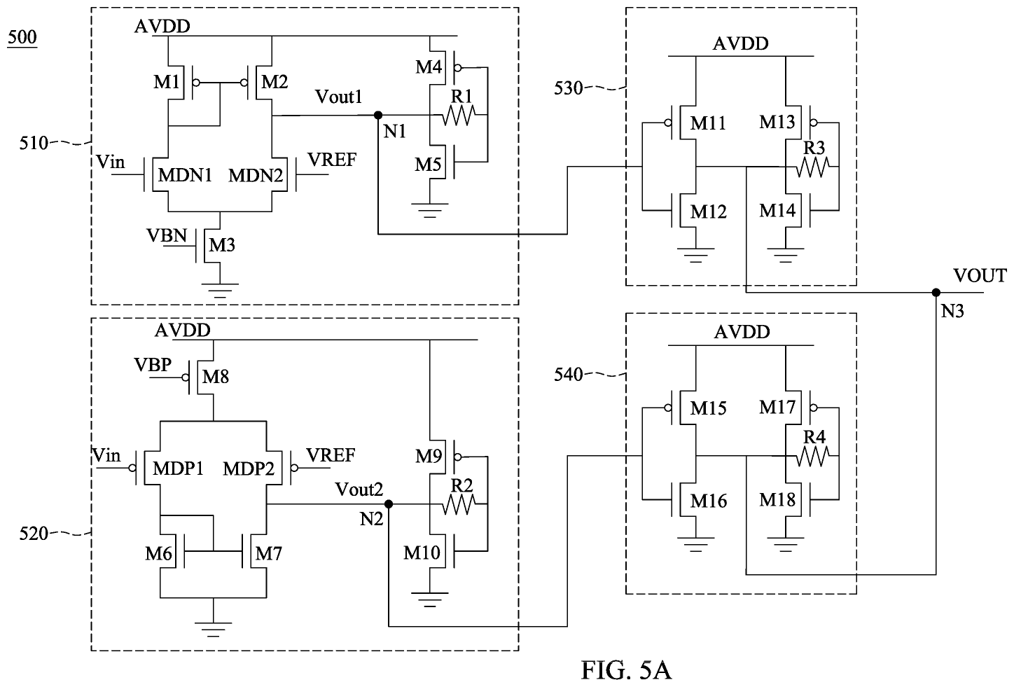

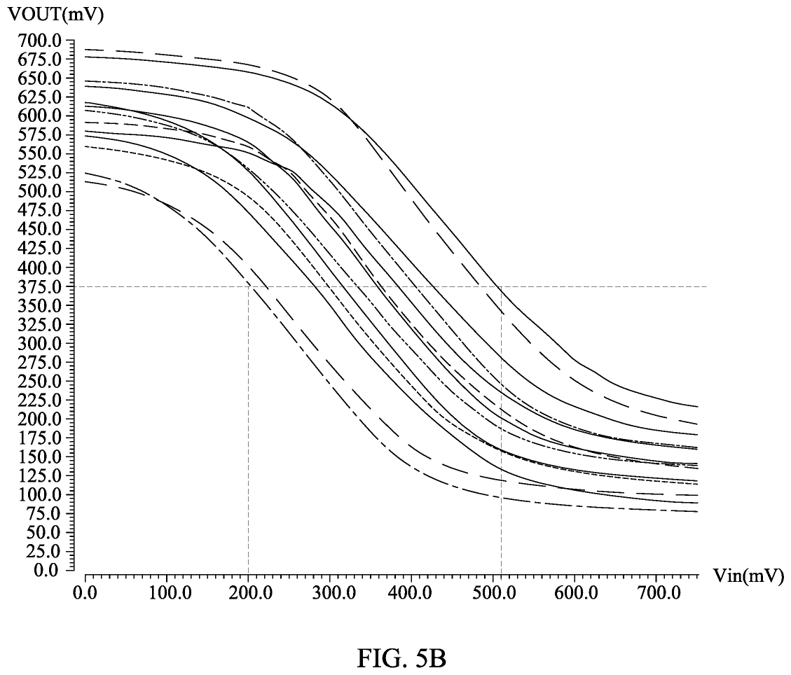

FIG. 5A is a schematic diagram of a comparator circuit 500 in accordance with an embodiment of the present disclosure. FIG. 5B is a diagram illustrating the relationship between the input voltage Vin and the output voltage VOUT of the comparator circuit 500 in FIG. 5A. Please refer to FIG. 4 and FIGS. 5A-5B.

The comparator circuit 410 shown in FIG. 4 may be implemented by the comparator circuit 500 shown in FIG. 5A. The comparator circuit 500 may include a first differential amplifier 510, a second differential amplifier 520, and CMOS inverter circuits 530 and 540. The first differential amplifier 510 may include transistors M1˜M5 and transistors MDN1˜MDN2. For example, the transistors M1˜M3 and MDN1˜MND2 may form an N-type differential amplifier. The input voltage Vin and the reference voltage VREF may be provided to the gates of the transistors MDN1 and MDN2, respectively. The transistors M1 and M2 may form a current mirror, and the transistor M3 may function as a current source, which is controlled by a bias voltage VBN. The output terminal (i.e., node N1) of the N-type differential amplifier may be connected to an active load which includes transistors M4˜M5 and a resistor R1. For example, the transistors M4 and M5 may use diode-connected configurations, and the gates of the transistors M4 and M5 are connected together, and the drains of the transistors M4 and M5 are also connected together. In addition, the gates of the transistors M4 and M5 may be electrically connected to the drains of the transistors M4 and M5 through the resistor R1.

In addition, the output terminal (i.e., node N1) of the N-type differential amplifier may be connected to the gates of transistors M11 and M12 which are input terminals of the CMOS inverter circuit 530. That is, the output voltage Vout1 of the N-type differential amplifier may be provided to the input terminals of the CMOS inverter circuit 530. The transistors M11 and M12 may form a CMOS inverter, and the output terminal (i.e., node N3) of the CMOS inverter may be connected to another active load which includes transistors M13˜M14 and a resistor R3. The transistors M13 and M14 may use diode-connected configurations, and the gates of the transistors M13 and M14 are connected together, and the drains of the transistors M13 and M14 are also connected together. In addition, the gates of the transistors M13 and M14 may be electrically connected to the drains of the transistors M13 and M14 through the resistor R1.

The transistors M6˜M8 and MDP1˜MNP2 may form a P-type differential amplifier. The input voltage Vin and the reference voltage VREF may be provided to the gates of the transistors MDP1 and MDP2, respectively. The transistors M6 and M7 may form a current mirror, and the transistor M8 may function as a current source, which is controlled by a bias voltage VBP. The output terminal (i.e., node N2) of the P-type differential amplifier may be connected to an active load which includes transistors M9˜M10 and a resistor RR. For example, the transistors M9 and M10 may use diode-connected configurations, and the gates of the transistors M9 and M10 are connected together, and the drains of the transistors M9 and M10 are also connected together. In addition, the gates of the transistors M9 and M10 may be electrically connected to the drains of the transistors M9 and M10 through the resistor R2.

In addition, the output terminal (i.e., node N2) of the P-type differential amplifier may be connected to the gates of transistors M15 and M16 which are input terminals of the CMOS inverter circuit 540. That is, the output voltage Vout2 of the P-type differential amplifier may be provided to the input terminals of the CMOS inverter circuit 540. The transistors M15 and M16 may form a CMOS inverter, and the output terminal (i.e., node N3) of the CMOS inverter may be connected to another active load which includes transistors M17˜M18 and a resistor R3. The transistors M17 and M18 may use diode-connected configurations, and the gates of the transistors M17 and M18 are connected together, and the drains of the transistors M17 and M18 are also connected together. In addition, the gates of the transistors M17 and M18 may be electrically connected to the drains of the transistors M17 and M18 through the resistor R4.

Furthermore, the output terminals (i.e., node N3) of the CMOS inverter circuit 530 and 540 are connected together to provide an output voltage VOUT. The relationship between the input voltage Vin and the output voltage VOUT may be illustrated by FIG. 5B. The curves shown in FIG. 5B may represent the voltage cross points under different conditions, such as the manufacturing process, voltage, temperature, etc. The range of the voltage cross points may be approximately between 200 mv and 500 mv, as shown in FIG. 5B.

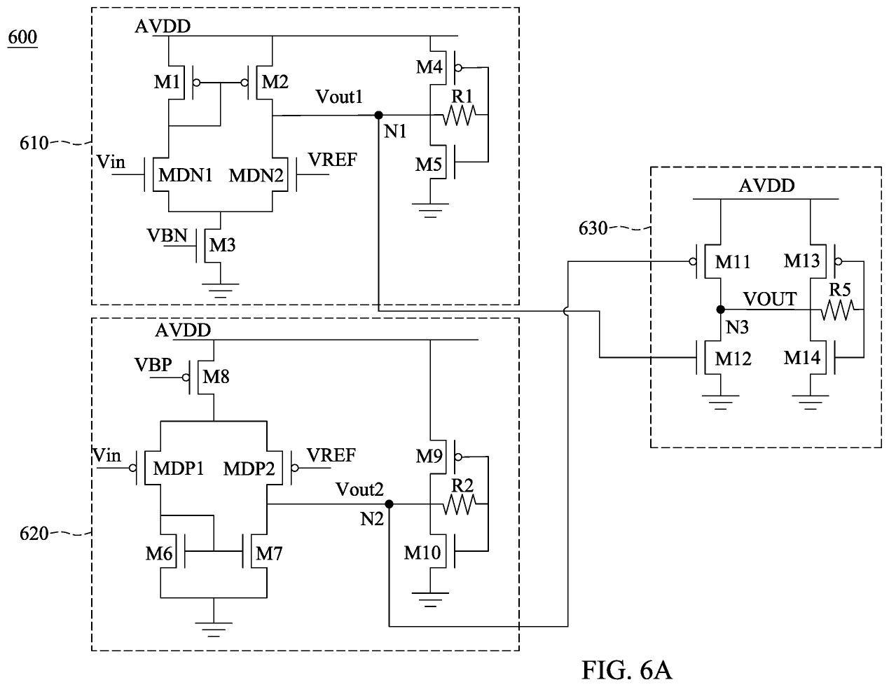

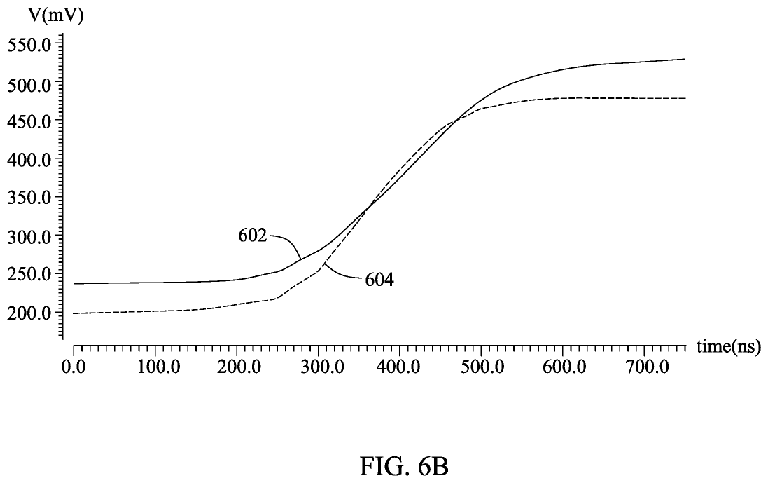

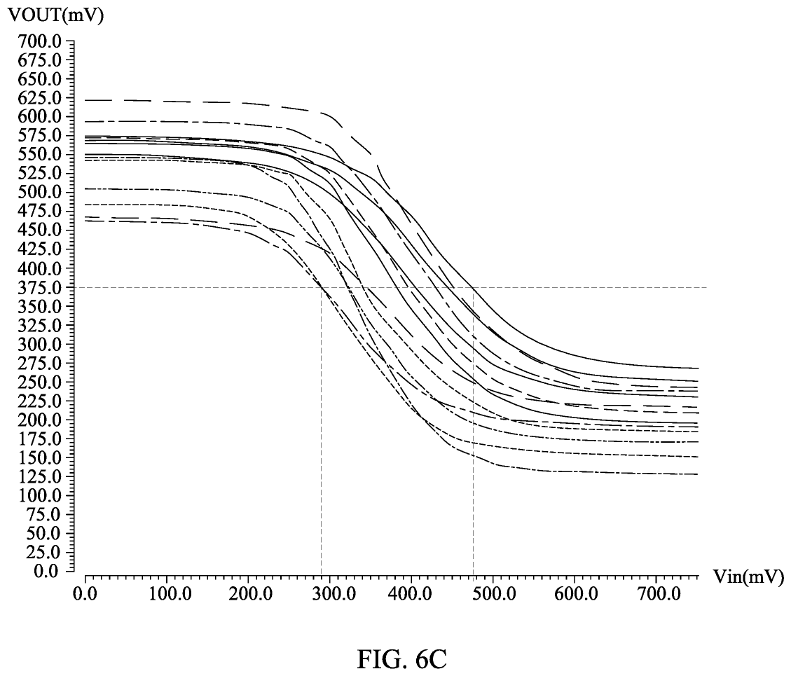

FIG. 6A is a schematic diagram of a comparator circuit 600 in accordance with an embodiment of the present disclosure. FIG. 6B is a diagram illustrating the voltages Vout1 and Vout2 of the comparator circuit 600 over time in FIG. 6A. FIG. 6C is a diagram illustrating the relationship between the input voltage Vin and the output voltage VOUT of the comparator circuit 600 in FIG. 6A. Please refer to FIG. 4 and FIGS. 6A-6C.

In some embodiments, the comparator circuit 410 shown in FIG. 4 may be implemented by the comparator circuit 600 shown in FIG. 6A. The comparator circuit 600 shown in FIG. 6A may be similar to the comparator circuit 500 shown in FIG. 5A, with the difference therebetween that the output terminals of the differential amplifiers 610 and 620 are respectively connected to a first input terminal and a second input terminal of the CMOS inverter circuit 630. More specifically, the output terminal (i.e., node N1) of the differential amplifier 610 may be connected to the gate of the transistor M12, which is the first input terminal of the CMOS inverter circuit 630. The output terminal (i.e., node N2) of the differential amplifier 620 may be connected to the gate of the transistor M11, which is the second input terminal of the CMOS inverter circuit 630. In other words, the first input terminal and the second input terminal of the CMOS inverter circuit 630 can be respectively controlled by the output voltages Vout1 and Vout2 generated by the differential amplifiers 610 and 620.

Here, curves 602 and 604 illustrate the output voltage Vout1 and Vout2 over time. The output voltages Vout1 and Vout2 may automatically track the comparison result of the differential amplifiers 610 and 620 under different conditions of the process, voltage, and temperature. In addition, the range of the voltage cross points of the comparator circuit 600 may be approximately between 300 mv and 500 mv, as shown in FIG. 6C. More specifically, the variation of the voltage cross points of the comparator circuit 600 can be reduced in comparison with the comparator circuit 500.

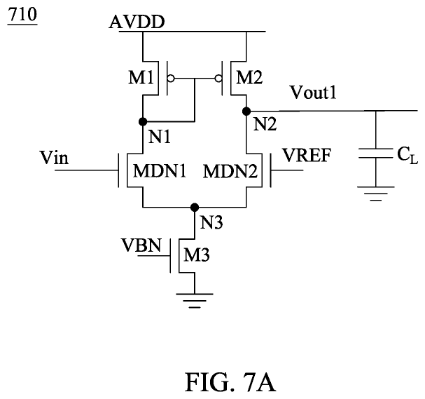

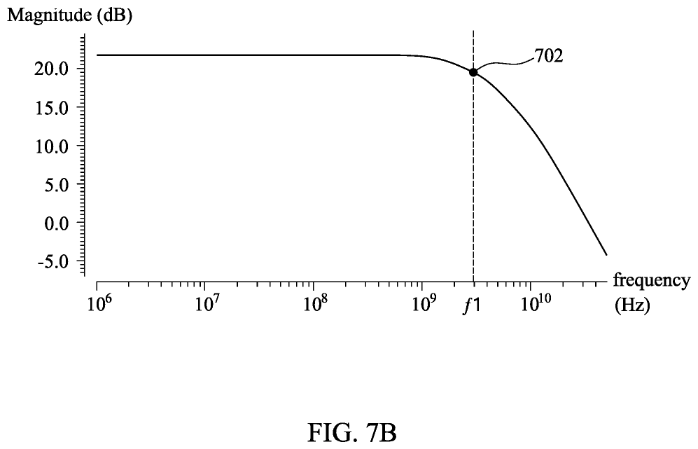

FIG. 7A is a schematic diagram of a differential amplifier 710 in accordance with the embodiments of FIG. 5A and FIG. 6A. FIG. 7B is a Bode plot illustrating the frequency response of the differential amplifier 710 in FIG. 7A. Please refer to FIGS. 5A, 6A, and 7A-7B.

The differential amplifiers 510 and 610 in FIGS. 5A and 6A may include the differential amplifier 710 shown in FIG. 7. The differential amplifier 710 may be a single-ended differential amplifier or an N-type differential amplifier. One input terminal of the differential amplifier 710 is provided with the input voltage Vin, and the other input terminal of the differential amplifier 710 is provided with the reference voltage VREF. In addition, the output terminal (i.e., node N2) of the differential amplifier 710 may be connected with a load capacitance C_{L}.

Given that rₒ₂ and rₒ₄ respectively denote the output resistances of the transistors M2 and MDN2, the small-signal gain (or transfer function)

$$\frac{{V}_{out 1}}{{V}_{in}}$$

of the differential amplifier 710 can be expressed by formula (1) as follows.

$$\frac{{V}_{out 1}}{{V}_{in}} = {g}_{m} \times ( {r}_{o 2} // {r}_{o 4} // \frac{1}{{sC}_{L}} ) = {g}_{m} \frac{{r}_{o 2} \times {r}_{o 4}}{1 + {sC}_{L} ( {r}_{o 2} + {r}_{o 4} )} \qquad ( 1 )$$

where gₘ denotes the transconductance of the differential amplifier 710. In addition, the pole wₚ₁ of the transfer function

$$\frac{{V}_{out 1}}{{V}_{in}}$$

can be expressed by formula (2) as follows.

$${ω}_{p 1} = \frac{1}{{C}_{L} ( {r}_{o 2} + {r}_{o 4} )} \qquad ( 2 )$$

It should be noted that the small-signal gain (or transfer function) and pole of the single-ended differential amplifier of the differential amplifier 520 or 620 can be derived in a similar manner.

In some embodiments, the Bode plot of the transfer function

$$\frac{{V}_{out 1}}{{V}_{in}}$$

can be illustrated by FIG. 7B, where a 3 db bandwidth frequency f1 is approximately 2.90685 GHz, and the corresponding magnitude at the 3 db bandwidth frequency f1 is approximately 19.7153 dB. Therefore, the bandwidth of the differential amplifier 710 is approximately 2.90685 GHz, which may be inadequate for 5G applications requiring a bandwidth of 32 Gbps or above.

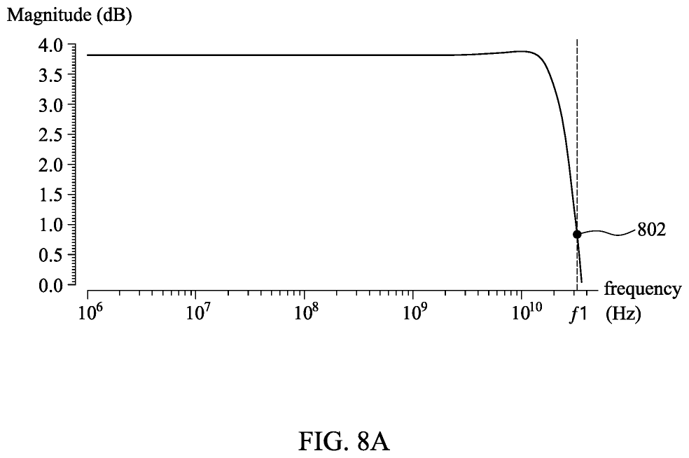

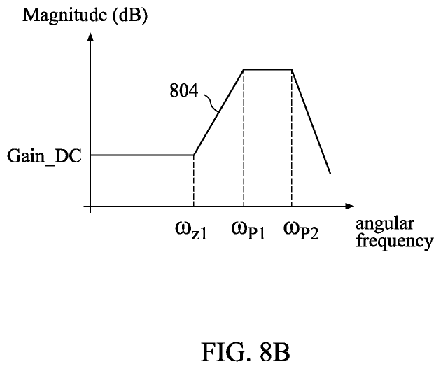

FIG. 8A is a Bode plot illustrating the frequency response of the differential amplifier 610 in FIG. 6. FIG. 8B is a diagram illustrating the frequency response of the differential amplifier 610 in FIG. 6. Please refer to FIG. 6, FIG. 7A, and FIGS. 8A-8B.

In some embodiments, the differential amplifier 610 shown in FIG. 6A may be obtained by connecting an active load (including transistors M4˜M5) to the output terminal of the differential amplifier 710 shown in FIG. 7A. In an example, rₒ₂ and rₒ₄ respectively denote the output resistances of the transistors M2 and MDN2. The impedance Zₛ of the active load can be expressed by formula (3) as follows.

$${Z}_{s} = \frac{1}{{g}_{m 2}} ( \frac{1 + {sC}_{gs} {R}_{g}}{1 + \frac{{sC}_{gs}}{{g}_{m 2}}} ) \qquad ( 3 )$$

where gₘ₂ denotes the transconductance of the active load; C_{gs} denotes the coupling capacitance between the gate and source of the transistor M4 or M5; Rg denotes the resistance R1. Thus, the small-signal gain (or transfer function)

$$\frac{{V}_{out 1}}{{V}_{in}}$$

of the differential amplifier 610 can be expressed by formula (4) as follows.

$$\frac{{V}_{out 1}}{{V}_{in}} = {g}_{m} \times ( {r}_{o 2} // {r}_{o 4} // \frac{1}{{sC}_{L}} // {Z}_{s} ) = \frac{{g}_{m}}{{g}_{m 2}} \frac{{r}_{o 2} \times {r}_{o 4} \times ( 1 + {sC}_{gs} {R}_{g} )}{\frac{{s}^{2} {C}_{L} {C}_{gs} ( {r}_{o 2} + {r}_{o 4} + {R}_{g} )}{{g}_{m 2}} + s ( {r}_{o 2} + {r}_{o 4} + ( {C}_{gs} + {C}_{L} ) / {g}_{m 2} ) + 1} \qquad ( 4 )$$

where gₘ denotes the transconductance of the differential amplifier 710; C_{L} denotes the load capacitance of the differential amplifier 610.

Thus, the DC gain Gain_DC of the differential amplifier 610 is equal to gₘ/gₘ₂. In addition, the transfer function of the differential amplifier 610 may have one zero ω_{Z1} and two poles ω_{P1} and ω_{P2} that can be respectively expressed by formulae (5), (6), and (7) as follows.

$${ω}_{Z 1} = \frac{1}{{C}_{gs}} \qquad ( 5 )$$

$${ω}_{P 1} = \frac{1}{{C}_{L}} ( {r}_{o 2} + {r}_{o 4} + \frac{1}{{g}_{m 2}} + \frac{{C}_{gs}}{{g}_{m 2} {C}_{L}} ) \qquad ( 6 )$$

$${ω}_{P 2} = \frac{1}{{C}_{L}} ( {r}_{o 2} + {r}_{o 4} + \frac{1}{{g}_{m 2}} + \frac{{C}_{gs}}{{g}_{m 2} {C}_{L}} ) / {C}_{gs} ( {r}_{o 2} + {r}_{o 4} + {R}_{g} ) \qquad ( 7 )$$

In an embodiment, the 3 db bandwidth frequency f1 at point 802 may be approximately 31.6 GHz, and the magnitude corresponding to the 3 db bandwidth frequency f1 may be approximately 0.81 dB, as shown in FIG. 8A. Specifically, the bandwidth of the differential amplifier 610 (i.e., including an active load) shown in FIG. 6A may be approximately equal to 31.6 GHz, which is significantly improved in comparison with the bandwidth of the single-ended differential amplifier 710 shown in FIG. 7A.

In some embodiments, the zero ω_{Z1} may be much lower than the first pole ω_{P1} and the second pole ω_{P2}. The DC gain of the differential amplifier 610 may be kept at a first constant from a very low angular frequency, and it can increase with a slew rate of 20 dB/decade until the first pole ω_{P1} is met. The DC gain may be kept at a second constant from the first pole ω_{P1} until the second pole ω_{P2} is met. The DC gain may decrease with a slew rate of −20 dB/decade after the second pole ω_{P2} is met, as shown in FIG. 8B.

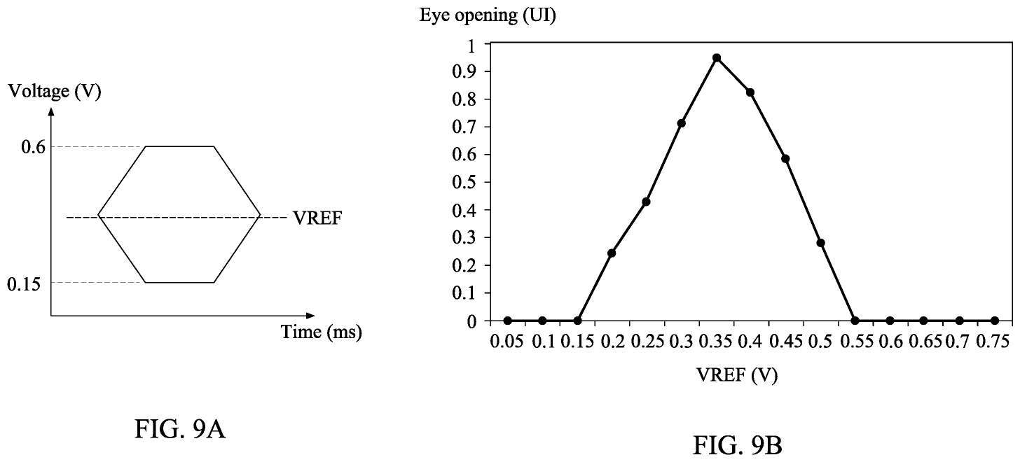

FIG. 9A is an eye diagram of the comparator circuit 600 in accordance with the embodiment of FIG. 6A. FIG. 9B is a diagram illustrating the relationship between the reference voltage VREF and the eye opening in accordance with the embodiment of FIG. 6A. Please refer to FIG. 6A and FIGS. 9A-9B.

In some embodiments, the comparator circuit 600 may include complementary types of differential amplifiers (e.g., N-type differential amplifier 610 and P-type differential amplifier 620) that can be used to achieve a wide range of the reference voltage VREF. For example, when the reference voltage VREF is much smaller than 0.5*AVDD, the transistor MDN2 may be turned off, and thus the N-type differential amplifier may be not capable of providing a high gain to compare the input voltage Vin and the reference voltage VREF. At this time, since the reference voltage VREF is much smaller than 0.5*AVDD, the transistor MDP2 may be turned on, and the P-type differential amplifier may be capable of providing a high gain to compare the input voltage Vin and the reference voltage VREF.

When the reference voltage VREF is close to the voltage AVDD, the transistor MDP2 may be turned off, and thus the P-type differential amplifier may be not capable of providing a high gain to compare the input voltage Vin and the reference voltage VREF. At this time, since the reference voltage VREF is higher than 0.5*AVDD, the transistor MDN2 may be turned on, and the N-type differential amplifier may be capable of providing a high gain to compare the input voltage Vin and the reference voltage VREF.

More specifically, a wide range of the reference voltage VREF can be achieved using the complementary types of differential amplifiers. In addition, the BIST circuit 130 can sweep the reference voltage VREF and the data strobe signal delayed by the digitally controlled delay line 114 to build an eye diagram, as shown in FIG. 9A. The range of the reference voltage VREF may be approximately between 0.15V and 0.6V. When the reference voltage VREF is approximately equal to the average of 0.15V and 0.6V, the eye diagram shown in FIG. 9A may have the widest opening in one unit interval (UI). In addition, the eye opening with respect to the reference voltage VREF can be built in a similar manner, wherein the eye opening may be expressed in units of unit intervals (UI).

In an embodiment, the present disclosure provides a receiver circuit, which includes: a first comparator circuit, a second comparator circuit, and an inverter circuit. The inverter circuit has a first input terminal and a second input terminal. A first output terminal of the first comparator circuit is electrically connected to the first input terminal of the inverter circuit, and a second output terminal of the second comparator circuit is electrically connected to the second input terminal of the inverter circuit.

In another embodiment, the present disclosure provides a receiver circuit, which includes a first comparator circuit, a second comparator circuit, a first inverter circuit, and a second inverter circuit. A first output terminal of the first comparator circuit is electrically connected to a first input terminal of the first inverter circuit, and a second output terminal of the second comparator circuit is electrically connected to a second input terminal of the second inverter circuit, wherein a third output terminal of the first inverter circuit is connected to a fourth output terminal of the second inverter circuit.

In yet another embodiment, the present disclosure provides a semiconductor device, which includes a plurality of receiver circuits. Each of the plurality of receiver circuits includes a receiver amplifier, a first delay circuit, a digitally controlled delay line, and a D flip-flop. The receiver amplifier is configured to receive a data signal from an input connection element, and amplify voltage swing of the received data signal. The first delay circuit is configured to delay the amplified data signal. The digitally controlled delay line is configured to receive a data strobe signal, and to delay the data strobe signal. The D flip-flop is configured to record the delayed amplified data signal in response to the delayed data strobe signal.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. A receiver circuit, comprising:
a first comparator circuit;
a second comparator circuit; and
an inverter circuit, having a first input terminal and a second input terminal,
wherein a first output terminal of the first comparator circuit is electrically connected to the first input terminal of the inverter circuit, and a second output terminal of the second comparator circuit is electrically connected to the second input terminal of the inverter circuit.

2. The receiver circuit of claim 1, wherein the first comparator circuit comprises a first single-ended differential amplifier, and a first active load,
wherein the second comparator circuit comprises a second single-ended differential amplifier, and a second active load.

3. The receiver circuit of claim 1, wherein the inverter circuit comprises a CMOS (complementary metal oxide semiconductor) inverter and a third active load.

4. The receiver circuit of claim 2, wherein the first single-ended differential amplifier comprises a first input terminal receiving an input voltage, and a second input terminal receiving a reference voltage,
wherein the second comparator circuit comprises a third input terminal receiving the input voltage, and a fourth input terminal receiving the reference voltage.

5. The receiver circuit of claim 4, wherein the first active load comprises:
a first P-type transistor having a gate connected to a first node, a source connected to a power supply voltage, and a drain connected to a second node;
a first N-type transistor having a gate connected to the first node, a source being grounded, and a drain connected to the second node; and
a resistor, coupled between the first node and the second node,
wherein the second node is the first output terminal of the first comparator circuit.

6. The receiver circuit of claim 4, wherein the second active load comprises:
a first P-type transistor having a gate connected to a first node, a source connected to a power supply voltage, and a drain connected to a second node;
a first N-type transistor having a gate connected to the first node, a source being grounded, and a drain connected to the second node; and
a resistor, coupled between the first node and the second node,
wherein the second node is connected to the second output terminal of the second comparator circuit.

7. The receiver circuit of claim 3, wherein the CMOS inverter comprises:
a first P-type transistor, having a gate connected to the second output terminal of the second comparator circuit, a source connected to a power supply voltage, and a drain connected to a first node; and
a first N-type transistor, having a gate connected to the first output terminal of the first comparator circuit, a source being grounded, and a drain connected to the first node.

8. The receiver circuit of claim 7, wherein the third active load comprises:
a second P-type transistor, having a gate connected to a second node, a source connected to the power supply voltage, and a drain connected to the first node;
a second N-type transistor, having a gate connected to the second node, a source being grounded, and a drain connected to the first node; and
a resistor, coupled between the first node and the second node,
wherein the first node is connected to an output terminal of the receiver circuit.

9. A receiver circuit, comprising:
a first comparator circuit;
a second comparator circuit; and
a first inverter circuit;
a second inverter circuit;
wherein a first output terminal of the first comparator circuit is electrically connected to a first input terminal of the first inverter circuit, and a second output terminal of the second comparator circuit is electrically connected to a second input terminal of the second inverter circuit,
wherein a third output terminal of the first inverter circuit is connected to a fourth output terminal of the second inverter circuit.

10. The receiver circuit of claim 9, wherein the first comparator circuit comprises a first single-ended differential amplifier, and a first active load,
wherein the second comparator circuit comprises a second single-ended differential amplifier, and a second active load.

11. The receiver circuit of claim 9, wherein the first inverter circuit comprises a first CMOS (complementary metal oxide semiconductor) inverter and a third active load,
wherein the second inverter circuit comprises a second CMOS (complementary metal oxide semiconductor) inverter and a fourth active load.

12. The receiver circuit of claim 10, wherein the first single-ended differential amplifier comprises a first input terminal receiving an input voltage, and a second input terminal receiving a reference voltage,
wherein the second comparator circuit comprises a third input terminal receiving the input voltage, and a fourth input terminal receiving the reference voltage.

13. The receiver circuit of claim 12, wherein the first active load comprises:
a first P-type transistor having a gate connected to a first node, a source connected to a power supply voltage, and a drain connected to a second node;
a first N-type transistor having a gate connected to the first node, a source being grounded, and a drain connected to the second node; and
a resistor, coupled between the first node and the second node,
wherein the second node is connected to the first output terminal of the first comparator circuit.

14. The receiver circuit of claim 12, wherein the second active load comprises:
a first P-type transistor having a gate connected to a first node, a source connected to a power supply voltage, and a drain connected to a second node;
a first N-type transistor having a gate connected to the first node, a source being grounded, and a drain connected to the second node; and
a resistor, coupled between the first node and the second node,
wherein the second node is connected to the second output terminal of the second comparator circuit.

15. The receiver circuit of claim 11, wherein the first CMOS inverter comprises:
a first P-type transistor, having a gate connected to the second output terminal of the second comparator circuit, a source connected to a power supply voltage, and a drain connected to a first node; and
a first N-type transistor, having a gate connected to the first output terminal of the first comparator circuit, a source being grounded, and a drain connected to the first node.

16. The receiver circuit of claim 15, wherein the third active load comprises:
a second P-type transistor, having a gate connected to a second node, a source connected to the power supply voltage, and a drain connected to the first node;
a second N-type transistor, having a gate connected to the second node, a source being grounded, and a drain connected to the first node; and
a resistor, coupled between the first node and the second node,
wherein the first node is connected to an output terminal of the receiver circuit.

17. A semiconductor device, comprising:
a plurality of receiver circuits, each of the plurality of receiver circuits comprising:
a receiver amplifier, configured to receive a data signal from an input connection element, and amplify voltage swing of the received data signal;
a first delay circuit, configured to delay the amplified data signal;
a digitally controlled delay line, configured to receive a data strobe signal, and to delay the data strobe signal; and
a D flip-flop, configured to record the delayed amplified data signal in response to the delayed data strobe signal.

18. The semiconductor device of claim 17, further comprising:
a built-in self-test (BIST) circuit, configured to build an eye diagram by sweeping the delayed data strobe signal and a reference voltage used by the receiver amplifier in each receiver circuit.

19. The semiconductor device of claim 18, wherein each of the plurality of receiver circuits comprises:
a first comparator circuit;
a second comparator circuit; and
an inverter circuit, having a first input terminal and a second input terminal,
wherein a first output terminal of the first comparator circuit is electrically connected to the first input terminal of the inverter circuit, and a second output terminal of the second comparator circuit is electrically connected to the second input terminal of the inverter circuit.

20. The semiconductor device of claim 19, wherein the first comparator circuit comprises a first single-ended differential amplifier, and a first active load,
wherein the second comparator circuit comprises a second single-ended differential amplifier, and a second active load.
